(19) United States
(12) Patent Application Publication
(10) Pub. No.: US 2025/0265151 A1
(43) Pub. Date: Aug. 21, 2025

(54) NON-VOLATILE MEMORY DEVICE, CONTROLLER, AND MEMORY SYSTEM

(71) Applicant: SAMSUNG ELECTRONICS CO., LTD., SUWON-SI (KR)

(72) Inventors: Changon Lee, Suwon-si (KR); Myungkyu Kim, Suwon-si (KR); Junyeong Seok, Suwon-si (KR); Wansoo Choi, Suwon-si (KR)

(21) Appl. No.: 18/949,110

(22) Filed: Nov. 15, 2024

(30) Foreign Application Priority Data
Feb. 20, 2024 (KR) 10-2024-0024462

(51) Int. Cl. G06F 11/10; G06F 13/16

(52) U.S. Cl. CPC G06F 11/1068; G06F 11/1016; G06F 13/1689

(57) ABSTRACT

A non-volatile memory device, a controller, and a memory system are provided. The non-volatile memory device includes a first pin configured to receive a command and an address from a controller and to communicate first data with the controller, a memory cell array including a plurality of memory cells, and control logic configured to control an operation on the plurality of memory cells based on the command and the address, wherein the first data is communicated through the first pin during an idle time, wherein the idle time starts when the command and the address are received through the first pin and ends after the first data is communicated through the first pin.

### CROSS-REFERENCE

This application claims priority under 35 U.S.C. § 119 to Korean Patent Application No. 10-2024-0024462, filed on Feb. 20, 2024 in the Korean Intellectual Property Office, the disclosure of which is incorporated by reference herein in its entirety.

### FIELD

The present disclosure relates to a memory device, and more particularly, to a non-volatile memory device, a controller, and a memory system including the non-volatile memory device and the controller.

### DISCUSSION

Storage devices, such as solid-state drives (SSDs), are widely used. For example, a storage device may correspond to a memory system including a non-volatile memory device, such as a flash memory device, and a controller controlling the non-volatile memory device. With the rising performance of storage devices, the data input/output speed between a non-volatile memory device and a controller in a storage device is increasing. A non-volatile memory device may communicate input/output signals with a controller through predefined pins according to protocols. A non-volatile memory device may receive a command and an address from a controller through particular input/output pins and communicate data with the controller through these input/output pins. According to such an input/output interface, data may not be transmitted while a command or an address is being transmitted, and the efficiency of the input/output interface may decrease. Therefore, a memory system or non-volatile memory device including an input/output interface enabling data to be efficiently transmitted between a non-volatile memory device and a controller is desired.

### SUMMARY

Embodiments of the present disclosure provide a memory system, controller, and non-volatile memory device configured to enhance input/output efficiency by decreasing a transmission time of a command, an address, and data.

According to an embodiment of the present disclosure, a non-volatile memory device includes: a first pin configured to receive a command and an address from a controller and to communicate first data with the controller; a memory cell array including a plurality of memory cells; and control logic configured to control an operation of the plurality of memory cells based on the command and the address, wherein the first data is communicated through the first pin during an idle time, wherein the idle time starts when the command and the address are received through the first pin and ends after the first data is communicated through the first pin.

According to an embodiment of the present disclosure, a controller includes: a first pin configured to transmit a command and an address to a non-volatile memory device, and to communicate first data with the non-volatile memory device; a parity bit generator configured to generate a parity bit; and an error correction code (ECC) circuit configured to detect or correct an error based on the first data or the second data, wherein the first data is communicated through the first pin during an idle time, wherein the idle time starts when the controller transmits the command and the address through the first pin and ends after the first data is communicated through the first pin.

According to an embodiment of the present disclosure, a memory system includes: a non-volatile memory device; and a controller configured to transmit a command and an address to the non-volatile memory device and to communicate first data and second data with the non-volatile memory device, wherein the non-volatile memory device includes: a memory input/output pin configured to receive the command and the address, from the controller and to communicate first data with the controller; a memory data pin configured to communicate the second data with the controller; a memory cell array including a plurality of memory cells; and control logic configured to control an operation of the plurality of memory cells based on the command and the address, wherein the controller includes: a controller input/output pin configured to transmit the command and the address to the non-volatile memory and to communicate the first data with the non-volatile memory device; a controller data pin configured to communicate the second data with the non-volatile memory device; a parity bit generator configured to generate a parity bit; and an error correction code (ECC) circuit configured to detect or correct an error based on the first data or the second data, wherein the first data is transmitted and received through the controller and memory input/output pins during an idle time, wherein the idle time starts when the controller transmits the command and the address through the controller input/output pin and ends after the first data is communicated through the controller input/output pin.

### BRIEF DESCRIPTION OF THE DRAWINGS

Embodiments will be more clearly understood from the following detailed description taken in conjunction with the accompanying drawings, in which:

FIG. 1 is a block diagram illustrating a memory system, including a controller and a non-volatile memory device, according to an embodiment;

FIG. 2 is a timing diagram illustrating examples of signals in a write operation of the non-volatile memory device in FIG. 1, according to an embodiment;

FIG. 3 is a flowchart illustrating a write operation between the controller and the non-volatile memory device in FIG. 1, according to an embodiment;

FIG. 4 is a timing diagram illustrating examples of signals in a read operation of the non-volatile memory device in FIG. 1, according to an embodiment;

FIG. 5 is a flowchart illustrating a read operation between the controller and the non-volatile memory device in FIG. 1, according to an embodiment;

FIG. 6 is a block diagram illustrating a memory system according to an embodiment;

FIG. 7 is a block diagram illustrating a memory system according to an embodiment;

FIG. 8 is a block diagram illustrating a non-volatile memory device according to an embodiment;

FIG. 9 is a block diagram illustrating an example of applying a non-volatile memory device to a solid-state drive (SSD) system, according to an embodiment; and

FIG. 10 is a block diagram illustrating a user system including a memory system or module, according to an embodiment.

### DETAILED DESCRIPTION

Hereinafter, the inventive concept is disclosed by way of example in connection with illustrative embodiments that may be described in greater detail with reference to the accompanying drawings.

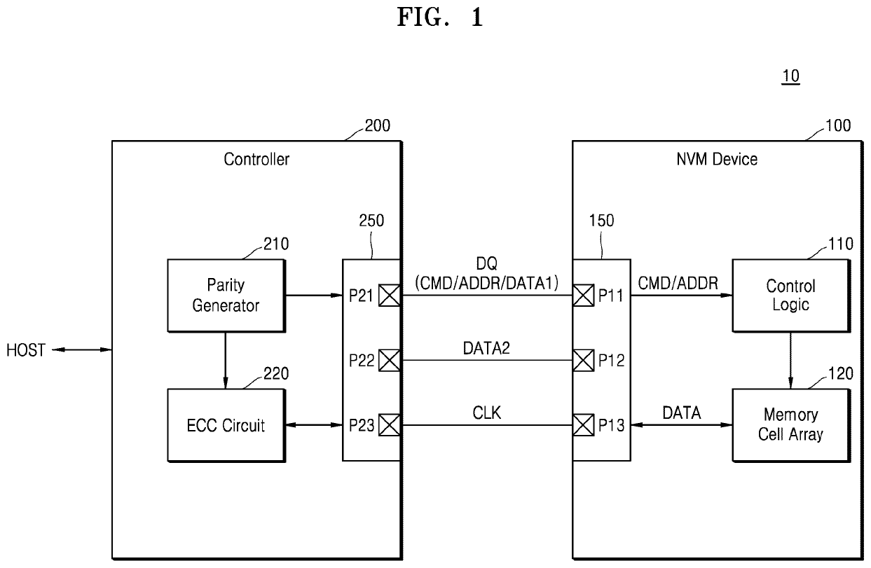

As shown in FIG. 1, a memory system is indicated generally by the reference numeral 10.

Referring to FIG. 1, the memory system 10 may include a non-volatile memory (NVM) device 100 and a controller 200. The NVM device 100 may include a memory interface 150, a memory cell array 120 including a plurality of memory cells, and control logic 110. The controller 200 may include a controller interface 250, a parity generator 210, and an error correction code (ECC) circuit 220. The memory interface 150 of the NVM device 100 may include first to third pins P11, P12, and P13. The controller interface 250 of the controller 200 may include first to third pins P21, P22, and P23. The first to third pins 21, 22 and 23 of the controller interface 250 may connect to the first to third pins 11, 12 and 13 of the memory interface 150, respectively. For example, the memory system 10 may include an NVM device 100 such as a solid-state drive (SSD).

The controller 200 may control the NVM device 100 to read data from the NVM device 100 in response to a read request from a host, or to write data to the NVM device 100 in response to a write request from the host. According to an embodiment, the controller 200 may be referred to as a memory controller. In greater detail, the controller 200 may provide a command CMD and an address ADDR to the NVM device 100 to control program, read, and erase operations of the NVM device 100. Data to be programmed and read data may be transmitted between the controller 200 and the NVM device 100. Data may include first data DATA1 and second data DATA2.

In an embodiment, the command CMD and the address ADDR may be transmitted from the controller 200 to the NVM device 100 through the same input/output channel as the data. For example, the controller 200 may sequentially transmit the command CMD and the address ADDR to the NVM device 100 through the input/output channel. Subsequently, the controller 200 may transmit write data to be programmed to the NVM device 100 or receive read data that has been read from the NVM device 100.

The controller 200 may transmit the command CMD and the address ADDR to the NVM device 100 through the first pin P21 and may communicate the first data DATA1 with the NVM device 100 through the first pin P21. According to an embodiment, the first pin P21 may be referred to as an input/output pin. For example, the first pin P21 may include a plurality of input/output pins, which may be electrically connected to the NVM device 100 through a plurality of input/output lines. The first data DATA1, transmitted and received between the controller 200 and the NVM device 100 through the first pin P21, may include a parity bit. For example, data may include the first data DATA1 and the second data DATA2. The first data DATA1 may include a parity bit and the second data DATA2 may include normal data provided or requested by the host. For example, the first data DATA1 communicated through the first pin P21 may include a parity bit generated by the parity generator 210.

However, the present disclosure is not limited thereto. For example, in an embodiment, a channel through which the command CMD and the address ADDR are transmitted may be separate from a channel through which data is transmitted.

The controller 200 may communicate the second data DATA2 with the NVM device 100 through the second pin P22. According to an embodiment, the second pin P22 may be referred to as a data pin. The second data DATA2 communicated between the controller 200 and the NVM device 100 through the second pin P22 need not include a parity bit. For example, the second data DATA2 may include normal data. Normal data may refer to data that does not include a parity bit that is generated by the parity generator 210.

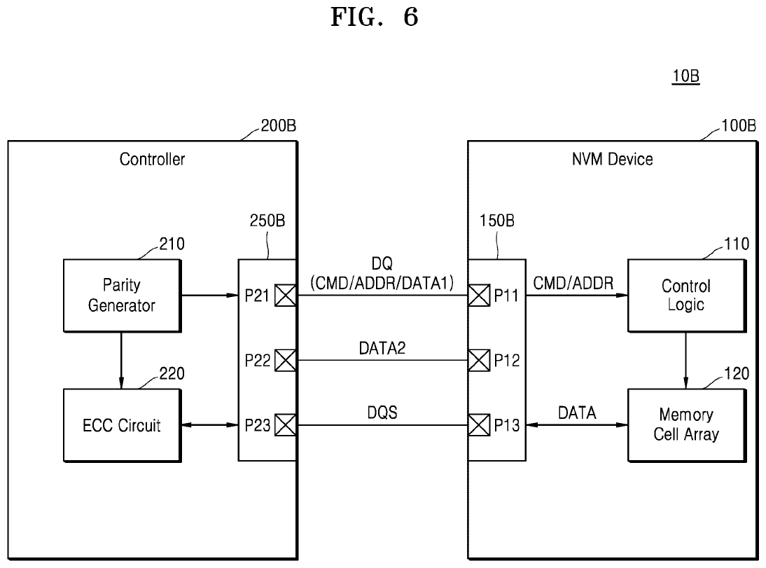

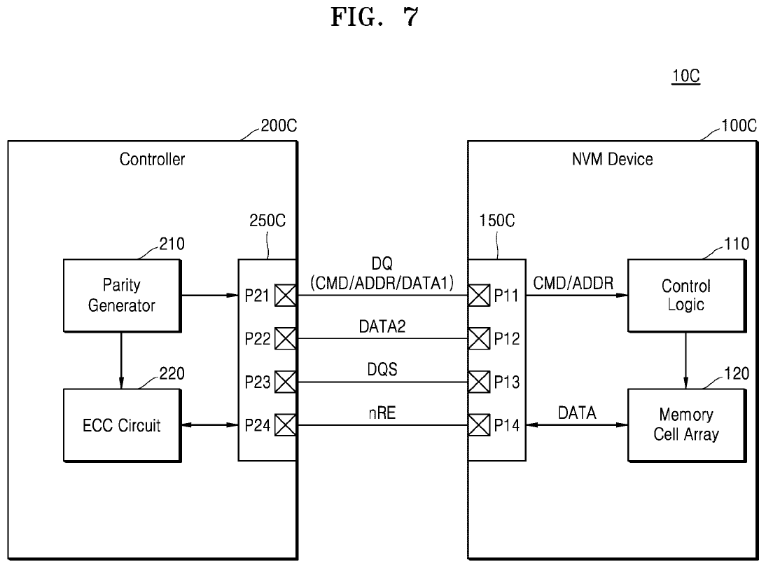

The controller 200 may transmit a clock signal CLK to the NVM device 100 through the third pin P23. According to an embodiment, the third pin P23 may be referred to as a clock pin. In an embodiment, the clock signal CLK may be a data input/output clock signal (e.g., a data strobe signal), such as described below with reference to FIG. 6. In an embodiment, the clock signal CLK may be a write enable signal. In an embodiment, the clock signal CLK may be a read enable signal. In an embodiment, the clock signal CLK may include a plurality of signals, e.g., a write enable signal and a read enable signal. An example of this is described below with reference to FIG. 7. In an embodiment, the clock signal CLK may be provided as a differential signal. In an embodiment, the clock signal CLK may toggle in a period in which the command CMD and the address ADDR are transmitted or in a period in which data is transmitted and received.

The controller 200 may synchronize the command CMD, the address ADDR, the first data DATA1, and the second data DATA2 with the clock signal CLK and transmit the command CMD, the address ADDR, the first data DATA1, and the second data DATA2 to the NVM device 100 in synchronization with the clock signal CLK. In an embodiment, the command CMD, the address ADDR, the first data DATA1, and the second data DATA2 may be synchronized with a rising edge of the clock signal CLK. In an embodiment, the command CMD, the address ADDR, the first data DATA1, and the second data DATA2 may be synchronized with a falling edge of the clock signal CLK. In an embodiment, the command CMD, the address ADDR, the first data DATA1, and the second data DATA2 may be synchronized with a rising edge and a falling edge of the clock signal CLK. For example, the command CMD, the address ADDR, the first data DATA1, and the second data DATA2 may be transmitted to the NVM device 100 in a double data rate (DDR) mode.

In an embodiment, a time period after the controller 200 transmits the command CMD and the address ADDR to the NVM device 100, through the first pin P21, until an operation of the NVM device 100 is completed, may be referred to as an idle time.

For example, the controller 200 may transmit the write command CMD and the address ADDR to the first pin P11 of the memory interface 150 through the first pin P21 of the controller interface 250, and transmit the second data DATA2 to the second pin P12 of the memory interface 150 through the second pin P22 of the controller interface 250. The time from when the controller 200 transmits the write command CMD and the address ADDR to the first pin P11 through the first pin P21 until the NVM device 100 completes a write operation may be referred to as an idle time. During the idle time, the controller 200 may transmit the first data DATA1 and the second data DATA2, which are to be written, to the NVM device 100, such as through the first pins P21 and P11. Alternatively, the controller 200 may transmit the first data DATA1 through the first pins P21 and P11 and transmit the second data DATA2 through the second pins P22 and P12 during the idle time.

As another example, the controller 200 may transmit the read command CMD and the address ADDR to the NVM device 100 through the first pin P21. Here, the time from when the controller 200 transmits the read command CMD and the address ADDR to the first pin P11 of the NVM device 100 through the first pin P21 until the NVM device 100 completes a read operation may be referred to as an idle time. During the idle time, the controller 200 may receive the first data DATA1 read from the NVM device 100 through the first pin P21.

Accordingly, when the first data DATA1 is transmitted and received through the first pin P21 of the controller 200 and the first pin P11 of the NVM device 100 during the idle time, the memory system 10 may increase input/output efficiency by reducing the transmission time of the first data DATA1. In other words, the memory system 10 may support this high-efficiency input/output interface between the controller 200 and the NVM device 100.

The parity generator 210 may generate a parity bit based on the first data DATA1 and/or the second data DATA2, such as to support data stability.

The ECC circuit 220 may correct an error in data transmitted to or received from the NVM device 100. For example, the ECC circuit 220 may correct an error in data read from the NVM device 100. In some embodiments, the ECC circuit 220 may include an ECC encoder and an ECC decoder. The ECC encoder may perform ECC encoding on data to be written to the NVM device 100. The ECC decoder may perform ECC decoding on data read from the NVM device 100 and detect or correct an error in the read data. Although FIG. 1 shows an embodiment where the parity generator 210 and the ECC circuit 220 are embodied as separate circuits in the controller 200, the parity generator 210 and the ECC circuit 220 may alternatively be embodied as a single circuit.

The controller interface 250 may be electrically connected to the memory interface 150 through an input/output channel. The controller interface 250 may include the first pin P21, the second pin P22, and the third pin P23. The memory interface 150 may include the first pin P11, the second pin P12, and the third pin P13. The input/output channel may include at least one line connection between the first pins of the controller interface and the memory interface, at least one line connection between the second pins of the controller interface and the memory interface, and at least one line connection between the third pins of the controller interface and the memory interface,

The NVM device 100 may receive the command CMD and the address ADDR through the first pin P11 and may communicate the first data DATA1 with the controller 200 through the first pin P11. According to an embodiment, the first pin P11 may be referred to as an input/output pin. For example, the first pin P11 may include a plurality of input/output pins, which may be electrically connected to the controller 200 through a plurality of input/output lines.

In an embodiment, a channel through which the command CMD and the address ADDR are transmitted may be separate from a channel through which the first data DATA1 and the second data DATA2 are transmitted. Accordingly, the NVM device 100 may receive the command CMD and the address ADDR from the controller 200 through the first pin P11, and communicate the first data DATA1 and the second data DATA2 with the controller 200 through the first pins P11 and P21 and the second pins P12 and P22, respectively.

The NVM device 100 may communicate the second data DATA2 with the controller 200 through the second pin P12. According to an embodiment, the second pin P12 may be referred to as a data pin. In an embodiment, the second data DATA2, when communicated between the controller 200 and the NVM device 100 through the second pin P12, need not include a parity bit.

The NVM device 100 may receive the clock signal CLK from the controller 200 through the third pin P13. According to an embodiment, the third pin P13 may be referred to as a clock pin.

The control logic 110 may generally control various operations of the NVM device 100. The control logic 110 may receive the command CMD and the address ADDR, and control an operation on a plurality of memory cells of the memory cell array 120 based on the command CMD and the address ADDR. The control logic 110 may generate control signals for controlling other elements of the NVM device 100 according to the command CMD and the address ADDR. For example, the control logic 110 may generate control signals for programming data to the memory cell array 120 or reading data from the memory cell array 120.

The memory cell array 120 may store data under control of the control logic 110. The memory cell array 120 may output the first data DATA1 and the second data DATA2, which are stored in the memory cell array 120, through the first pin P11 and the second pin P12, respectively, under control of the control logic 110. The memory cell array 120 may include a plurality of memory cells. For example, the memory cells may include flash memory cells. However, embodiments are not limited thereto.

In an embodiment, the memory system 10 may include an internal memory embedded in an electronic device. For example, the memory system 10 may include an SSD, an embedded universal flash storage (UFS) memory device, or an embedded multimedia card (eMMC). In an embodiment, the memory system 10 may include an external memory removably mounted on an electronic device. For example, the memory system 10 may include a UFS memory card, a compact flash (CF) card, a secure digital (SD) card, a mini-SD card, a micro-SD card, an extreme digital (xD) card, or a memory stick.

The memory system 10 and the host may form a storage system. For example, the storage system may include a personal computer, a data server, a network-attached storage device, an Internet of things (IoT) device, or a portable electronic device. The portable electronic device may include a laptop computer, a mobile phone, a smartphone, a tablet personal computer (PC), a personal digital assistant (PDA), an enterprise digital assistant (EDA), a digital still camera, a digital video camera, an audio device, a portable multimedia player (PMP), a personal navigation device (PND), an MP3 player, a handheld game console, an e-book, or a wearable device.

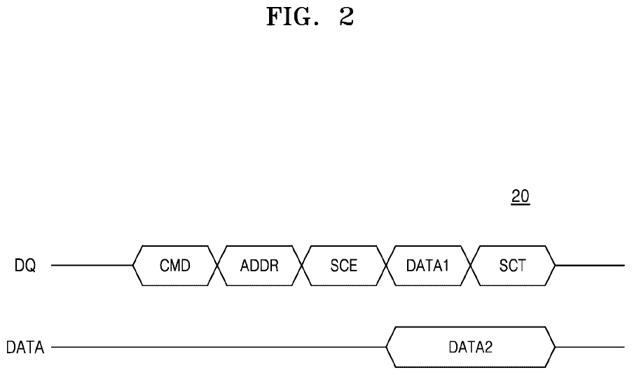

Turning to FIG. 2, a signals example for a write operation is indicated generally by the reference numeral 20. For example, the signals may be for a write operation of the NVM device 100 in FIG. 1, according to an embodiment.

Referring to FIGS. 1 and 2, a data signal line DQ may be connected between the first pins P11 and P21. The command CMD, the address ADDR, a chip selection enable signal SCE, the first data DATA1, and a chip termination enable signal SCT may be transmitted through the data signal line DQ.

The command CMD may be transmitted through the first pins P11 and P21. For example, the command CMD may correspond to a write command.

The address ADDR may be transmitted through the first pins P11 and P21. For example, the address ADDR may correspond to a write address.

The chip selection enable signal SCE may be transmitted through the first pins P11 and P21. For example, the chip selection enable signal SCE may be enabled in a write operation.

The first data DATA1 may be transmitted from the first pin P21 of the controller 200 to the first pin P11 of the NVM device 100. For example, data transmitted and received through the first pins P11 and P21 may include a parity bit. In an embodiment, because the first data DATA1 may be transmitted and received through the first pin P21 of the controller 200 and the first pin P11 of the NVM device 100 during an idle time, the communication time of the first data DATA1 may be reduced so that input/output efficiency may be increased.

The chip termination enable signal SCT may be transmitted through the first pins P11 and P21. For example, the chip termination enable signal SCT may be enabled when a write operation is completed.

The second data DATA2 may be transmitted from the second pin P22 of the controller 200 to the second pin P12 of the NVM device 100. A data line DATA may be connected between the second pins P12 and P22, and the second data DATA2 may be transmitted through the data line DATA.

The second data DATA2 may be transmitted and received through the second pins P12 and P22. For example, the second data DATA2 may be synchronized with a second edge of the chip selection enable signal SCE and a second edge of the chip termination enable signal SCT, without limitation thereto.

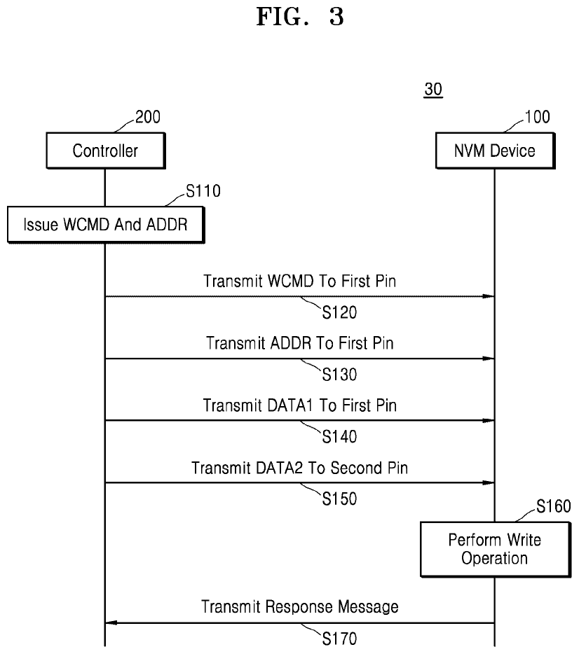

Turning now to FIG. 3, a write operation is indicated generally by the reference numeral 30. For example, the write operation may be between the controller 200 and the NVM device 100 in FIG. 1, according to an embodiment.

Referring to FIGS. 1 to 3, the controller 200 may issue a write command WCMD and an address ADDR in operation S110.

The controller 200 may transmit the write command WCMD to the NVM device 100 in operation S120. For example, the controller 200 may output the write command WCMD through its first pin P21 and output a toggling clock signal through its third pin P23. The write command WCMD may be output in synchronization with the clock signal. For example, the NVM device 100 may receive the write command WCMD through its first pin P11 and receive the clock signal through its third pin P13. The write command WCMD may be received in synchronization with the clock signal.

The controller 200 may transmit the address ADDR to the NVM device 100 in operation S130. For example, the controller 200 may output the address ADDR through its first pin P21 and output a toggling clock signal through its third pin P23. The address ADDR may be output in synchronization with the clock signal. For example, the NVM device 100 may receive the address ADDR through its first pin P11 and receive the clock signal through its third pin P13. The address ADDR may be received in synchronization with the clock signal.

The controller 200 may transmit the first data DATA1 to the NVM device 100 through its first pin P21 in operation S140. Here, the first data DATA1 may include a parity bit. For example, because the first data DATA1 may be transmitted through the respective first pins P11 and P21 during an idle time, the transmission time of the first data DATA1 may be reduced, and accordingly, input/output efficiency may be increased.

The controller 200 may transmit the second data DATA2 to the NVM device 100 through its second pins P12 and P22 in operation S150. Here, the second data DATA2 may be normal data that does not include a parity bit from the parity generator 210.

The NVM device 100 may perform a write operation in operation S160. In detail, the NVM device 100 may write the first data DATA1 and the second data DATA2 to the control logic 110.

The NVM device 100 may transmit a response message, which indicates that the write operation is completed, to the controller 200 in operation S170.

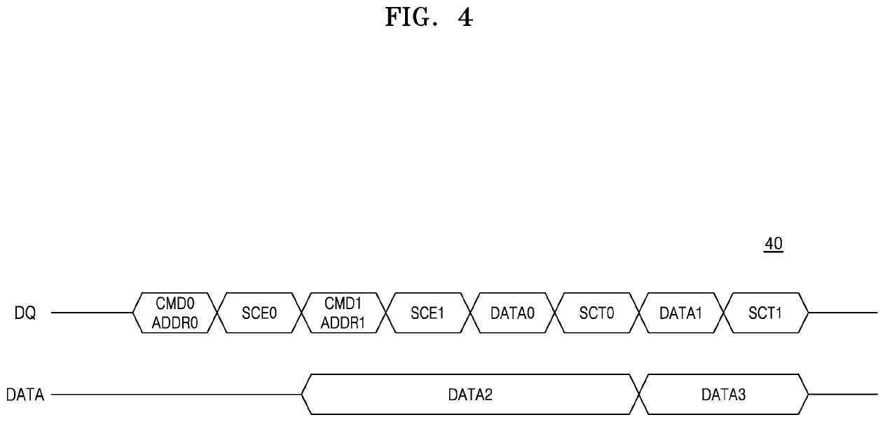

As shown in FIG. 4, a signals example for a read operation is indicated generally by the reference numeral 40. For example, the signals may be for a read operation of the NVM device 100 in FIG. 1, according to an embodiment.

Referring to FIGS. 1 and 4, commands CMD0 and CMD1, addresses ADDR0 and ADDR1, chip selection enable signals SCE0 and SCE1, data (e.g., DATA0 and DATA1) and chip termination enable signals SCT0 and SCT1 may be transmitted through the data signal line DQ.

The commands CMD0 and CMD1 may be sequentially transmitted through the first pins P11 and P21. For example, the commands CMD0 and CMD1 may correspond to a read command.

The addresses ADDR0 and ADDR1 may be sequentially transmitted through the first pins P11 and P21. For example, the addresses ADDR0 and ADDR1 may correspond to a read address.

The chip selection enable signals SCE0 and SCE1 may be sequentially transmitted through the first pins P11 and P21. For example, the chip selection enable signals SCE0 and SCE1 may be enabled in a read operation.

The data (e.g., DATA0 and DATA1) may be transmitted from the first pin P11 of the NVM device 100 to the first pin P21 of the controller 200. For example, data transmitted and received through the first pins P11 and P21 may include a parity bit. In an embodiment, because the data (e.g., DATA0 and DATA1) may be transmitted and received through the first pin P21 of the controller 200 and the first pin P11 of the NVM device 100 during an idle time, the communication time of the data (DATA0 and DATA1) may be reduced so that input/output efficiency may be increased.

The chip termination enable signals SCT0 and SCT1 may be transmitted through the first pins P11 and P21. For example, the chip termination enable signals SCT0 and SCT1 may be enabled when a read operation is completed.

Additional data (e.g., DATA2 and DATA3) may be transmitted and received from the second pin P12 of the NVM device 100 to the second pin P22 of the controller 200. A data line DATA may be connected between the second pins P12 and P22 and the additional data (e.g., DATA2 and DATA3) may be transmitted through the data line DATA.

The additional data (e.g., DATA2 and DATA3) may be transmitted and received through the second pins P12 and P22. For example, the additional data (e.g., DATA2 and DATA3) may be synchronized with the chip selection enable signals SCE0 and SCE1, respectively, and/or the chip termination enable signals SCT0 and SCT1, respectively.

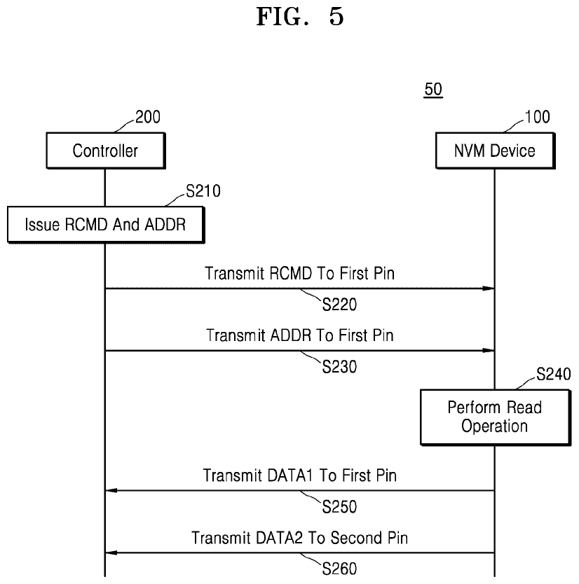

Turning to FIG. 5, a read operation is indicated generally by the reference numeral 50, For example, the read operation may be between the controller 200 and the NVM device 100 in FIG. 1, according to an embodiment.

Referring to FIGS. 1, 4, and 5, the controller 200 may issue a read command RCMD and an address ADDR in operation S210.

The controller 200 may transmit the read command RCMD to the NVM device 100 in operation S220. For example, the controller 200 may output the read command RCMD through its first pin P21 and output a toggling clock signal through its third pin P23. The read command RCMD may be output in synchronization with the clock signal. For example, the NVM device 100 may receive the read command RCMD through its first pin P11 and receive the clock signal through its third pin P13. The read command RCMD may be received in synchronization with the clock signal.

The controller 200 may transmit the address ADDR to the NVM device 100 in operation S230. For example, the controller 200 may output the address ADDR through its first pin P21 and output a toggling clock signal through its third pin P23. The address ADDR may be output in synchronization with the clock signal. For example, the NVM device 100 may receive the address ADDR through its first pin P11 and receive the clock signal through its third pin P13. The address ADDR may be received in synchronization with the clock signal.

The NVM device 100 may perform a read operation in operation S240. In greater detail, the NVM device 100 may read data from the memory cell array 120.

The NVM device 100 may transmit the first data (e.g., DATA0 and DATA1) to the controller 200 through its first pin P11 in operation S250. Here, the first data DATA1 may include a parity bit. For example, because the first data DATA1 may be transmitted and received through the first pins P11 and P21 during an idle time, the communication time of the first data DATA1 may be reduced so that input/output efficiency may be increased.

The NVM device 100 may transmit the second data (e.g., DATA2 and DATA3) to the controller 200 through the second pins P12 and P22 in operation S260. Here, the second data DATA2 may be normal data that does not include a parity bit from the parity generator 210.

Turning now to FIG. 6, a memory system according to an embodiment is indicated generally by the reference numeral 10B.

Referring to FIG. 6, the memory system 10B may include an NVM device 100B and a controller 200B. The memory system 10B may be similar to the memory system 10 of FIG. 1. The NVM device 100B may be similar to the NVM device 100 in FIG. 1. The controller 200B may be similar to the controller 200 in FIG. 1. The descriptions made with reference to FIG. 1 may also be applied to the present embodiment, and thus, substantially redundant description may be omitted.

The controller 200B may include a controller interface 250B. The controller interface 250B may include a first pin P21, a second pin P22, and a third pin P23. The third pin P23 may correspond to an alternative example of the third pin P23 in FIG. 1. According to an embodiment, the third pin P23 may be referred to as a data strobe signal pin. A data strobe signal DQS may be transmitted from the data strobe signal pin, e.g., the third pin P23, of the controller 200B to a data strobe signal pin, e.g., the third pin P13, of the NVM device 100B. In an embodiment, the data strobe signal DQS may toggle in a transmission period of the command CMD and the address ADDR or in a communication period of data.

The NVM device 100B may include a memory interface 150B. The memory interface 150B may include a first pin P11, a second pin P12, and a third pin P13. The third pin P13 may be referred to as a data strobe signal pin and may correspond to an alternative example of a clock pin, e.g., the third pin P13, in FIG. 1.

The data strobe signal DQS may be transmitted from the data strobe signal pin, e.g., the third pin P23, of the controller 200B to the data strobe signal pin, e.g., the third pin P13, of the NVM device 100B and may toggle. The command CMD, the address ADDR, the first data DATA1, and the second data DATA2 may be transmitted and received through the first pins P11 and P21 and/or the second pins P12 and P22 in synchronization with the data strobe signal DQS.

In an embodiment, the DQ and DATA2 lines of FIG. 6 may also switch roles based on the data strobe signal DQS.

The command CMD may be transmitted and received through the first pins P11 and P21 in synchronization with the data strobe signal DQS. For example, the command CMD may be synchronized with a rising edge of the data strobe signal DQS and may correspond to a write command.

The address ADDR may be transmitted and received through the first pins P11 and P21 in synchronization with the data strobe signal DQS. For example, the address ADDR may be synchronized with a rising edge of the data strobe signal DQS and may correspond to a write address.

The first data DATA1 may be transmitted and received through the first pins P11 and P21 in synchronization with the data strobe signal DQS. For example, the first data DATA1 may be synchronized with a rising edge of the data strobe signal DQS. Data transmitted and received through the first pins P11 and P21 may include a parity bit. In an embodiment, because the first data DATA1 may be transmitted and received through the first pin P21 of the controller 200B and the first pin P11 of the NVM device 100B during an idle time, the communication time of the first data DATA1 may be reduced so that input/output efficiency may be increased.

The second data DATA2 may be transmitted and received from the data pin, e.g., the second pin P22, of the controller 200B to the data pin, e.g., the second pin P12, of the NVM device 100B. A data line may be connected between the second pins P12 and P22. The second data DATA2 may be transmitted through the data line. For example, the second data DATA2 may be synchronized with the data strobe signal DQS.

As shown in FIG. 7, a memory system according to an embodiment is indicated generally by the reference numeral 10C.

Referring to FIG. 7, the memory system 10C may include an NVM device 100C and a controller 200C. The memory system 10C may correspond to an alternative example of the memory system 10 of FIG. 1. The NVM device 100C may correspond to an alternative example of the NVM device 100 in FIG. 1. The controller 200C may correspond to an alternative example of the controller 200 in FIG. 1. The descriptions made with reference to FIG. 1 may also be applied to the present embodiment, and thus, substantially redundant descriptions thereof may be omitted.

The controller 200C may include the controller interface 250C. The controller interface 250C may include a first pin P21, a second pin P22, a third pin P23, and a fourth pin P24. According to an embodiment, the third pin P23 may be referred to as a data strobe signal pin, and the fourth pin P24 may be referred to as a read enable signal pin. The third pin P23 and the fourth pin P24 may correspond to an alternate example of the clock pin, e.g., the third pin P23, in FIG. 1. A data strobe signal DQS may be transmitted to a third pin P13 of the NVM device 100C through the third pin P23 of the controller 200C. A read enable signal nRE may be transmitted to a fourth pin P14 of the NVM device 100C through the fourth pin P24 of the controller 200C.

The NVM device 100C may include the memory interface 150C. The memory interface 150C may include a first pin P11, a second pin P12, the third pin P13, and the fourth pin P14. The third pin P13 and the fourth pin P14 may correspond to an alternative example of the clock pin, e.g., the third pin P13, in FIG. 1.

The data strobe signal DQS may be transmitted from the data strobe signal pin, e.g., the third pin P23, of the controller 200C to the data strobe signal pin, e.g., the third pin P13, of the NVM device 100C and may toggle. The command CMD, the address ADDR, and data DATA1 and DATA2 may be transmitted and received through the first pins P11 and P21 and/or the second pins P12 and P22 in synchronization with the data strobe signal DQS.

The read enable signal nRE may be transmitted from the read enable signal pin, e.g., the fourth pin P24, of the controller 200C to the read enable signal pin, e.g., the fourth pin P14, of the NVM device 100C and may toggle. The command CMD, the address ADDR, the first data DATA1, and the second data DATA2 may be transmitted and received through the first pins P11 and P21 and/or the second pins P12 and P22 in synchronization with the read enable signal nRE.

In an embodiment, the read enable signal nRE may be transmitted from the read enable signal pin, e.g., the fourth pin P14, of the NVM device 100C to the read enable signal pin, e.g., the fourth pin P24, of the controller 200C and may toggle.

The command CMD may be transmitted from the first pin P21 of the controller 200C to the first pin P11 of the NVM device 100C in synchronization with the data strobe signal DQS or the read enable signal nRE. For example, the command CMD may be synchronized with a rising edge of the data strobe signal DQS or the read enable signal nRE and may correspond to a write command or a read command.

The address ADDR may be transmitted and received through the first pins P11 and P21 in synchronization with the data strobe signal DQS and/or the read enable signal nRE. For example, the address ADDR may be synchronized with a rising edge of the data strobe signal DQS or the read enable signal nRE and may correspond to a write address or a read address.

The first data DATA1 may be transmitted and received through the first pins P11 and P21 in synchronization with the data strobe signal DQS or the read enable signal nRE. For example, the first data DATA1 may be synchronized with a rising edge of the data strobe signal DQS or the read enable signal nRE. Data transmitted and received through the first pins P11 and P21 may include a parity bit. In an embodiment, because the first data DATA1 may be transmitted and received through the first pin P21 of the controller 200C and the first pin P11 of the NVM device 100C during an idle time, the communication time of the first data DATA1 may be reduced so that input/output efficiency may be increased.

The second data DATA2 may be transmitted and received from the data pin, e.g., the second pin P22, of the controller 200C to the data pin, e.g., the second pin P12, of the NVM device 100C. A data line may be connected between the second pins P12 and P22. The second data DATA2 may be transmitted through the data line. For example, the second data DATA2 may be synchronized with the data strobe signal DQS or the read enable signal nRE.

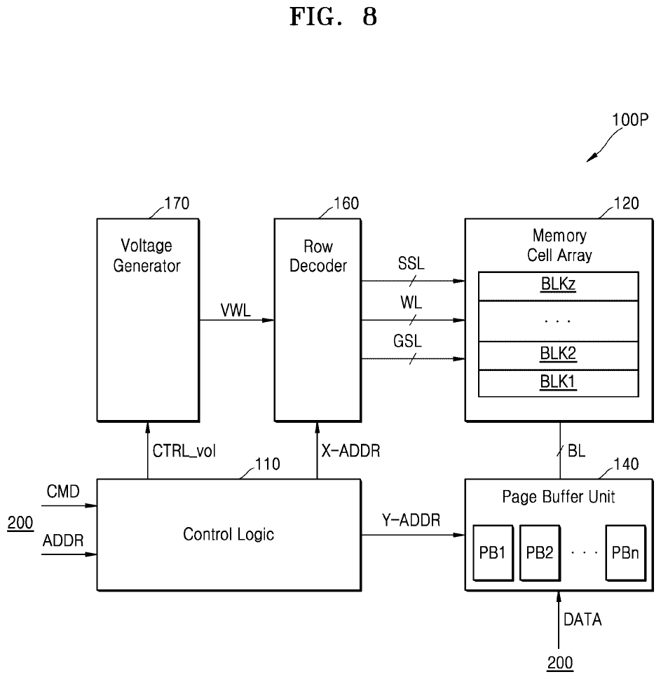

Turning to FIG. 8, part of an NVM device 100 of FIG. 1, 100B of FIGS. 6 and/or 100C of FIG. 7, less the corresponding memory interface 150, 150B or 150C according to an embodiment, is indicated generally by the reference numeral 100P.

Referring to FIG. 8, the NVM device part 100P may include the control logic 110, the memory cell array 120, a page buffer unit 140, a voltage generator 170, and a row decoder 160. The NVM device part 100P of the present embodiment may correspond to an example implementation of the NVM device 100 in FIG. 1, less the memory interface 150. The descriptions made with reference to FIGS. 1 to 7 may also be applied to the present embodiment. Substantially duplicate description may be omitted.

The NVM device 100B may further include a memory interface circuit, column logic, a pre-decoder, a temperature sensor, a command decoder, an address decoder, and/or the like.

The control logic 110 may generally control various operations of the NVM device 100. The control logic 110 may output various control signals in response to the command CMD and/or the address ADDR from the controller 200. For example, the control logic 110 may output a voltage control signal CTRL_vol, a row address X-ADDR, and a column address Y-ADDR.

The memory cell array 120 may include a plurality of memory blocks BLK1 to BLKz (where “z” is a positive integer). Each of the memory blocks BLK1 to BLKz may include a plurality of memory cells. For example, the memory cells may include NAND flash memory cells. However, the present disclosure is not limited thereto. In an embodiment, the memory cells may include resistive-type memory cells, such as resistive random access memory (ReRAM) cells, phase-change RAM (PRAM) cells, or magnetic RAM (MRAM) cells. The memory cell array 120 may be connected to the page buffer unit 140 through bit lines BL and to the row decoder 160 through word lines WL, string select lines SSL, and ground select lines GSL.

In an embodiment, the memory cell array 120 may include a three-dimensional (3D) memory cell array, which may include a plurality of NAND strings. Each of the NAND strings may include memory cells respectively connected to word lines, which may be vertically stacked on a substrate. The disclosures of U.S. Pat. Nos. 7,679,133, 8,553,466, 8,654,587, 8,559,235, and U.S. Patent Application Publication No. 2011/0233648 are incorporated by reference herein in their entireties.

In an embodiment, the memory cell array 120 may include a two-dimensional (2D) memory cell array, which may include a plurality of NAND strings arranged in rows and/or columns.

The page buffer unit 140 may include a plurality of page buffers PB1 to PBn (where “n” is an integer of at least 3). Each of the page buffers PB1 to PBn may be connected to memory cells through one of the bit lines BL. The page buffer unit 140 may select at least one of the bit lines BL in response to the column address Y-ADDR. The page buffer unit 140 may operate as a write driver or a sense amplifier according to an operation mode.

The voltage generator 170 may generate voltages for performing program, read, and erase operations of the memory cell array 120, based on the voltage control signal CTRL_vol. For example, the voltage generator 170 may generate a program voltage, a read voltage, a program verify voltage, and/or an erase voltage as a word line voltage VWL.

The row decoder 160 may select one of the word lines WL and one of the string select lines SSL in response to the row address X-ADDR.

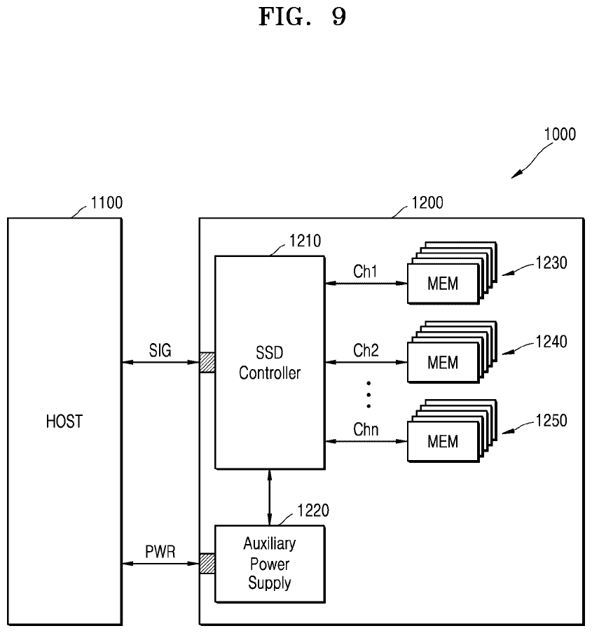

Turning now to FIG. 9, a solid-state drive (SSD) system is indicated generally by the reference numeral 1000. For example, the SSD system 1000 may include an NVM device according to an embodiment.

Referring to FIG. 9, the SSD system 1000 may include a host 1100 and an SSD 1200. The SSD 1200 may communicate signals SIG with the host 1100 through a signal connector and receive power PWR from the host 1100 through a power connector. The SSD 1200 may include an SSD controller 1210, an auxiliary power supply 1220, and memory devices (MEM) 1230, 1240, and 1250. The memory devices 1230, 1240, and 1250 may be connected to the SSD controller 1210 through channels Ch1 to Chn, respectively.

The SSD controller 1210 may be implemented using the controllers 200, 200B, and/or 200C described above with reference to FIGS. 1 to 8. In greater detail, the SSD controller 1210 may output a command and an address through a same input/output channel as data and may transmit the command and the address to the memory devices 1230, 1240, and 1250 in synchronization with a clock signal such as a data input/output clock signal.

The memory devices 1230, 1240, and 1250 may be implemented using the NVM devices 100, 100B, and/or 100C described above with reference to FIGS. 1 to 8. In greater detail, each of the memory devices 1230, 1240, and 1250 may receive a command and an address from the SSD controller 1210 through the same input/output channel as data and may receive the command and the address in synchronization with a clock signal such as a data input/output clock signal.

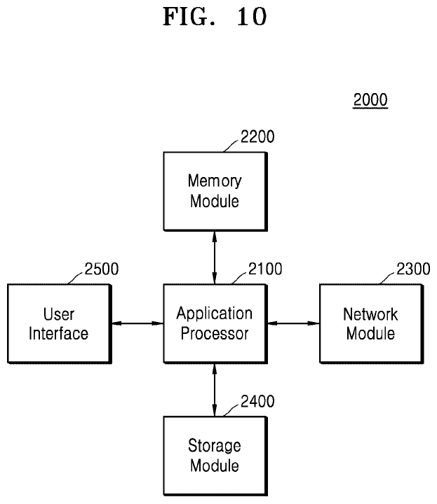

As shown in FIG. 10, a user system is indicated generally by the reference numeral 2000. For example, the user system 2000 may use an above-described memory system, according to an embodiment.

Referring to FIG. 10, the user system 2000 may include an application module 2100, a memory module 2200, a network module 2300, a storage module 2400, and a user interface 2500. For example, the memory module and/or the storage module may include a NVM device as described above.

The application module 2100 may drive elements of the user system 2000, an operating system (OS), a user program, and/or the like. For example, the application module 2100 may include controllers that control the elements of the user system 2000, interfaces, a graphics engine, and/or the like. The application module 2100 may be provided as a system-on-chip (SoC).

The memory module 2200 may operate as a main memory, an operating memory, a buffer memory, or a cache memory of the user system 2000. The memory module 2200 may include volatile RAM, such as dynamic RAM (DRAM), synchronous DRAM (SDRAM), DDR SDRAM, DDR2 SDRAM, DDR3 SDRAM, low-power DDR (LPDDR) SDRAM, LPDDR2 SDRAM, or LPDDR3 SDRAM, or non-volatile RAM, such as PRAM, ReRAM, MRAM, or ferroelectric RAM (FRAM). In an embodiment, the memory module 2200 may be an NVM device as described above. For example, the application module 2100 and the memory module 2200 may be packaged based on package-on-package (POP) and provided as a single semiconductor package.

The network module 2300 may communicate with external devices. For example, the network module 2300 may support wireless communication, such as code division multiple access (CDMA), global system for mobile communication (GSM), wideband CDMA (WCDMA), CDMA-2000, time division multiple access (TDMA), long term evolution (LTE), world interoperability for microwave access (Wimax), wireless local area network (WLAN), ultra wideband (UWB), Bluetooth, and/or wireless fidelity (Wi-Fi). For example, the network module 2300 may be included in the application module 2100.

The storage module 2400 may store data. For example, the storage module 2400 may store data received from the application module 2100. The storage module 2400 may transmit the stored data to the application module 2100. For example, the storage module 2400 may include non-volatile semiconductor memory, such as PRAM, MRAM, RRAM, NAND flash memory, Nor flash memory, and/or 3D NAND flash memory. In an embodiment, the storage module 2400 may include an NVM device and/or an SSD as described above. For example, the storage module 2400 may be provided as a removable drive, such as a memory card or an external drive, of the user system 2000.

According to an embodiment, the storage module 2400 may include a plurality of NVM devices, which may operate in substantially the same manner as the NVM device 100, 100B, or 100C described above with reference to FIGS. 1 to 9. The storage module 2400 may operate in the same manner as the memory system 10, 10B, or 10C described above with reference to FIGS. 1 to 9.

The user interface 2500 may include interfaces, which input data or an instruction to the application processor 2100 or output data to an external device. For example, the user interface 2500 may include user input interfaces, such as a keyboard, a key pad, a button, a touch panel, a touch screen, a touch pad, a touch ball, a camera, a microphone, a gyroscope sensor, a vibration sensor, and/or a piezoelectric element. The user interface 2500 may include user output interfaces, such as a liquid crystal display (LCD), an organic light emitting diode (OLED) display, an active matrix OLED (AMOLED) display, a LED display, a speaker, and/or a monitor.

While the present disclosure has been particularly shown and described with reference to embodiments thereof, it will be understood by those of ordinary skill in the pertinent art that various changes in form and details may be made therein without departing from the spirit and scope of the inventive concept as set forth in the following claims.

What is claimed is:

1. A non-volatile memory device comprising:
a first pin configured to receive a command and an address from a controller and to communicate first data with the controller;
a memory cell array including a plurality of memory cells; and
control logic configured to control an operation of the plurality of memory cells based on the command and the address,
wherein the first data is communicated through the first pin during an idle time,
wherein the idle time starts when the command and the address are received through the first pin and ends after the first data is communicated through the first pin.

2. The non-volatile memory device of claim 1, further comprising:
a second pin configured to communicate second data with the controller,
wherein the command is a write command,
wherein the idle time ends when the second data is received through the second pin.

3. The non-volatile memory device of claim 1, further comprising:
a second pin configured to communicate second data with the controller,
wherein the command is a read command,
wherein the idle time ends when the second data is transmitted through the second pin.

4. The non-volatile memory device of claim 3, wherein:
the first data includes a parity bit generated by the controller, and
the second data includes data except for the parity bit or a piece of data among pieces of data including the parity bit.

5. The non-volatile memory device of claim 1, further comprising:
a second pin configured to communicate second data with the controller; and
a clock pin configured to receive a clock signal from the controller,
wherein the clock signal toggles only in a period in which the command and the address are received from the controller or in a period in which the first data and the second data are communicated between the controller and the non-volatile memory device.

6. The non-volatile memory device of claim 5, wherein the clock signal corresponds to a data input/output clock signal.

7. The non-volatile memory device of claim 5, wherein:
the clock signal corresponds to a data strobe signal,
the clock pin corresponds to a data strobe pin, and
the command and the address are received from the controller through the first pin in synchronization with the data strobe signal.

8. The non-volatile memory device of claim 5, wherein:
the clock signal corresponds to a data strobe signal,
the command and the address are received from the controller through the first pin,
the first data is communicated between the controller and the non-volatile memory device through the first pin during the idle time,
the second data is communicated between the controller and the non-volatile memory device through the second pin,
the first data includes a parity bit generated by the controller, and
the second data does not include the parity bit.

9. The non-volatile memory device of claim 5, wherein
the clock signal corresponds to a read enable signal,
the command and the address are received from the controller through the first pin,
the first data is communicated between the controller and the non-volatile memory device through the first pin during the idle time,
the second data is communicated between the controller and the non-volatile memory device through the second pin,
the first data includes a parity bit generated by the controller, and
the second data does not include the parity bit.

10. The non-volatile memory device of claim 1, wherein the first pin is separate from the second pin.

11. A controller comprising:
a first pin configured to transmit a command and an address to a non-volatile memory device, and to communicate first data with the non-volatile memory device;
a parity bit generator configured to generate a parity bit; and
an error correction code (ECC) circuit configured to detect or correct an error based on the first data or the second data,
wherein the first data is communicated through the first pin during an idle time,
wherein the idle time starts when the controller transmits the command and the address through the first pin and ends after the first data is communicated through the first pin.

12. The controller of claim 11, further comprising:
a second pin configured to communicate second data with the non-volatile memory device;
wherein the idle ends when the second data is communicated through the second pin.

13. The controller of claim 11, wherein:
the first data includes the parity bit, and
the second data includes data except for the parity bit or a piece of data among pieces of data including the parity bit.

14. The controller of claim 11, further comprising a clock pin configured to transmit a clock signal to the non-volatile memory device.

15. The controller of claim 14, wherein
the clock signal corresponds to a data strobe signal,
the command and the address are transmitted to the non-volatile memory device through the first pin,
the first data is communicated between the controller and the non-volatile memory device through the first pin during the idle time,
the second data is communicated between the controller and the non-volatile memory device through the second pin,
the first data includes the parity bit, and
the second data does not include the parity bit.

16. The controller of claim 14, wherein
the clock signal corresponds to a read enable signal,
the command and the address are transmitted to the non-volatile memory device through the first pin,
the first data is communicated between the controller and the non-volatile memory device through the first pin during the idle time,
the second data is communicated between the controller and the non-volatile memory device through the second pin,
the first data includes the parity bit, and
the second data does not include the parity bit.

17. The controller of claim 11, wherein the first pin is separate from the second pin.

18. A memory system comprising:
a non-volatile memory device; and
a controller configured to transmit a command and an address to the non-volatile memory device and to communicate first data and second data with the non-volatile memory device,
wherein the non-volatile memory device includes:
a memory input/output pin configured to receive the command and the address, from the controller and to communicate first data with the controller;
a memory data pin configured to communicate the second data with the controller;
a memory cell array including a plurality of memory cells; and
control logic configured to control an operation of the plurality of memory cells based on the command and the address,
wherein the controller includes:
a controller input/output pin configured to transmit the command and the address to the non-volatile memory and to communicate the first data with the non-volatile memory device;
a controller data pin configured to communicate the second data with the non-volatile memory device;
a parity bit generator configured to generate a parity bit; and
an error correction code (ECC) circuit configured to detect or correct an error based on the first data or the second data,
wherein the first data is transmitted and received through the controller and memory input/output pins during an idle time,
wherein the idle time starts when the controller transmits the command and the address through the controller input/output pin and ends after the first data is communicated through the controller input/output pin.

19. The memory system of claim 18, wherein
the idle time ends when the second data is communicated between the controller and the non-volatile memory device through the controller and memory data pins.

20. The memory system of claim 18, wherein
the first data communicated through the controller and memory input/output pins during the idle time includes the parity bit generated by the parity bit generator, and
the second data communicated through the controller and memory data pins during the idle time does not include the parity bit.
